(19) United States
(12) Patent Application Publication
(10) Pub. No.: US 2026/0368876 A1
(43) Pub. Date: Nov. 19, 2026

(54) PERIODIC INSPECTION OF ELECTRICAL INSTALLATIONS

(71) Applicant: NEGA Grieshaber KG, Wolfach (DE)

(72) Inventors: Matthias Wöhrle, Schiltach (DE); Benjamin Schätzle, Schuttertal (DE)

(21) Appl. No.: 19/542,133

(22) Filed: Feb. 17, 2026

(30) Foreign Application Priority Data
Feb. 27, 2025 (DE) 102025107519.0

(51) Int. Cl. G06T 7/00

(52) U.S. Cl. CPC G06T 7/0002

(57) ABSTRACT

A computer-implemented method for periodic inspection of electrical installations such as field devices receives image data relating to an electrical installation, and evaluates the image data to determine whether the electrical installation is in the proper state. The evaluation of the image data is based on machine learning and/or artificial intelligence, and generates a report indicating whether the electrical installation is in the proper state. According to a further disclosed aspect, a system for the periodic inspection of electrical installations uses the described method. Also disclosed is a computer program product useable for the periodic inspection of electrical installations.

The invention relates to a computer-implemented method for the periodic inspection of electrical installations, in particular field devices. Furthermore, a system for the periodic inspection of electrical installations is proposed. According to a further aspect of the invention, a computer program product for periodic inspection is proposed.

Electrical installations must be regularly inspected to ensure safe operation. For example, a visual inspection can be carried out to identify certain defects such as contamination or corrosion. A periodic inspection is a recurring inspection or one that is to be performed on a regular basis. The procedure for carrying out periodic inspections is specified, for example, in DIN VDE 0105-100. Errors can occur during human-performed inspection. Certain defects can simply be overlooked by the human eye. Furthermore, the judgment of a human inspector is subjective. Misjudgments can also occur, for example, due to lack of attention or fatigue.

The invention is therefore based on the object of providing a method for the technical inspection of electrical installations, wherein the method should be objective and particularly reliable so as to ensure a higher level of safety of the installations. The method should also be quick and easy for the user to implement. A further object of the invention is to provide a system for inspecting electrical installations. Furthermore, a computer program product for inspecting electrical installations is to be provided. The object is achieved by the method according to claim 1, the system according to claim 14 and the computer program product according to claim 15. The dependent patent claims relate to optional embodiments of the invention.

It should be noted that the features listed in the independent and dependent claims can be combined in any way, insofar as technically sensible. This also applies across the boundaries of the claim categories and even if one patent claim is not dependent on another patent claim. The description additionally characterizes and specifies the invention, in particular in connection with the figures. If elements in the patent claims or the description are designated with numerical words such as “first,” “second,” etc., the numerical words serve only to make the elements distinguishable, but do not make any statement about an order, a total number or other properties of the elements, unless explicitly indicated.

According to a first aspect of the invention, a computer-implemented method for the periodic inspection of electrical installations, in particular field devices, is proposed. The method comprises the following steps: receiving image data relating to an electrical installation, evaluating the image data to determine whether the electrical installation is in the proper state, wherein the evaluation of the image data is based on machine learning and/or artificial intelligence, and generating a report indicating whether the electrical installation is in the proper state. This automatically determines whether the electrical installation still meets the technical requirements. Thanks to computer-aided evaluation, it can be avoided that the electrical installation continues to be operated, for example, due to a subjective misjudgment. This results in a higher safety standard.

This method can be carried out in particular by a mobile terminal, for example a smartphone or a tablet. However, it is also possible for the method to be carried out by another data processing device. To carry out a periodic inspection of an electrical installation, a user can record pictures or videos of the electrical installation, preferably using the camera of a mobile terminal. This generates image data, which are then evaluated according to the invention. The evaluation is preferably carried out using a method from the field of machine learning and/or artificial intelligence. For example, it is possible to use methods in the evaluation that are based on the use of neural networks. However, it is also possible to use other methods from the field of machine learning and/or artificial intelligence, for example statistical methods. According to the invention, the use of hybrid approaches is also possible, meaning that different methods from the field of machine learning can be combined.

For the purposes of the present invention, an electrical installation is to be understood as any electrical device, which in particular also includes electronic devices. The electrical installation is particularly advantageous as a field device. In process automation technology, field devices are frequently used to detect and/or influence process variables. Examples of such field devices are fill level measuring devices, limit level gauges and pressure gauges with sensors that detect the relevant process variables, namely fill level, limit level or pressure. However, a field device can also have an actuator, for example a control valve. The field devices known from the prior art typically have a housing, a sensor and a control unit arranged in the housing.

Evaluation is preferably carried out to check whether the electrical installation is in the proper state. According to the invention, a report will be issued stating whether the electrical installation is in the proper state. The report can, in principle, be brief and simply state whether the electrical installation is in the proper state. However, according to the invention, it is also possible for the report to contain additional information. According to the invention, the report can be a digital message (e.g., a notification in a program, an email, or an SMS). However, it is also possible for the report to be output in the form of a file, for example as a PDF file, or for the report to be written to or output into a database. The report is preferably output via an app, and particularly advantageously via an app that executes the method according to the invention on a mobile terminal.

The evaluation method according to the invention preferably uses a pre-trained model or AI model. The model can, for example, be in the form of a data set containing weightings from a neural network. The model is preferably trained to recognize, based on image data, whether an electrical installation is in the proper state. Preferably, the model is trained in such a way that it can be used in connection with different electrical installations. It is furthermore advantageous if the model has been trained such as to detect more than one type of fault in an electrical installation. The model is also preferably trained such as to classify the severity level of a defect or defects in the electrical installation and preferably to deduce therefrom whether the electrical installation is in the proper state. The model can be trained, in particular, using supervised learning. For training purposes, image data of electrical installations is processed as input data, wherein each electrical installation is assigned a label indicating whether it is in the proper state and/or whether it has defects. This process can use image data relating to an electrical installation or to different types of electrical installations. According to the invention, the input data can further comprise type information of the depicted electrical installation. This allows the model to learn how to perform an accurate assessment of different types of electrical installations.

When the image data is evaluated to determine whether the electrical installation is in the proper state, a check is preferably made as to whether the electrical installation has at least one safety-relevant defect and/or whether the electrical installation complies with current construction standards for electrical installations. In particular a check can be made as to whether the electrical installation is in the proper state in accordance with DIN VDE 0105-100. Preferably, only a visual inspection of the electrical installation is carried out, meaning that only visual data are processed. According to the invention, it is also possible to inspect properties of the electrical installation that are not based on DIN VDE 0105-100. In particular, a visual inspection can also be carried out according to another standard. However, the periodic inspection does not necessarily have to be carried out according to a standard.

According to an advantageous embodiment of the invention, the at least one safety-relevant defect is a defect that results from aging, wear and tear, operating and/or environmental conditions. Over time, for example, defects can occur in an electrical installation because materials or components age. This can lead to defects. Wear and tear, for example due to the wear of moving parts, is also possible. Furthermore, contamination is conceivable, in particular under extreme environmental conditions, for example underwater or inside a machine. The model underlying the evaluation is preferably trained to visually detect such defects in electrical installations.

According to an advantageous variant of the invention, the report specifies the at least one defect in the electrical installation. The report optionally includes information on the type of the at least one defect, information on the severity level of the at least one defect, information on the location of the at least one defect in the electrical installation, a proposal for remedying the at least one defect, and/or a proposal for inspection of the electrical installation by a technician. According to the invention, it is possible for the report to also contain additional information, notes and/or instructions. According to an advantageous embodiment of the invention, the report is archived and/or data contained in the report are archived, for example in a database. This allows for subsequent access to the results of the periodic inspection.

Evaluation preferably includes an assessment of the legibility of a nameplate of the electrical installation, an assessment of the degree of corrosion of a housing of the electrical installation, an assessment of the degree of contamination of a process connection point and/or housing of the electrical installation, and/or an assessment of the degree of physical damage to the electrical installation. According to the invention, it is possible to test for only one of these defects or for several of the defects. According to the invention, it is also possible to test for the presence of other defects.

To assess whether the electrical installation is in the proper state based on identified defects, the defects can, for example, be evaluated separately. For example, a severity level can be determined for each defect. According to an advantageous embodiment, if at least one defect exceeds a predefined severity level, a message is displayed indicating that the electrical installation is not in the proper state. According to an alternative embodiment of the invention, defects of different types are evaluated in total to determine whether the electrical installation is in the proper state. For example, the arithmetic mean of severity levels assigned to defects of different types can be determined. It is furthermore possible to weight different types of defects differently during evaluation.

It is advantageous if the image data include at least one digital photo of the electrical installation and/or at least one video recording of the electrical installation. A video recording within the meaning of the present invention includes all types of moving image recordings, in particular digital moving image recordings. Depending on the application scenario, it may be necessary to create either a digital photo or a video recording. For example, digital photos can be characterized by a higher level of detail than video recordings, although this often depends on the terminal used to capture the image data. It is furthermore possible that certain defects may only be recognizable on a video recording, for example, if a moving part of an electrical installation no longer moves or only moves to a limited extent.

It is advantageous if the method further includes receiving type information that specifies a type of the electrical installation, wherein the type information is used as the basis for evaluating the image data. Therefore, the type information is also preferably used in the evaluation. The type information can be, for example, a model number or a serial number of the electrical installation. In principle, this is information that allows the type of electrical installation to be identified. Preferably, an inspection history is retrieved based on the type information. This inspection history can, for example, be stored in a database. It can specify which inspections have been carried out in the past for a particular electrical installation and contain information on any defects found. According to an optional embodiment of the invention, features of the electrical installation that are checked during the evaluation of the image data are selected based on the inspection history.

Preferably, the type information is based on a data input from the user. For example, it is possible for a user to enter a type number of the electrical installation into a terminal, or to select the type of electrical installation to be checked on a display of the terminal. Alternatively or additionally, it is possible to extract the type information from the image data, wherein the type information is determined based on the appearance of the electrical installation, the content of a nameplate of the electrical installation and/or a QR code. The QR code can be, in particular, a QR code that is affixed to the electrical installation. A visual evaluation of the image data is carried out according to these features. This can be done in particular on the basis of artificial intelligence and/or machine learning. For example, a nameplate can be identified and its contents read. However, the type information can also be determined using other methods, for example by evaluating a QR code. According to an advantageous embodiment of the invention, the type information is determined before evaluation of the image data begins.

The method preferably includes issuing a first instruction to record a digital photo or video of the nameplate of the electrical installation. This preferentially causes a user to record image data that include the nameplate of the electrical installation. The type of electrical installation can be determined based on the nameplate. The first instruction can, for example, be issued to a user of a mobile terminal. Advantageously, the user of the mobile terminal uses an app that executes the method according to the invention. The first instruction can be contained, for example, in a text message, an audio message, or the like.

According to the invention, it may be provided for the method to furthermore include issuing a second instruction to record the image data, wherein the second instruction contains information on whether a digital photo or video is to be recorded, which detail of the electrical installation is to be captured by the recording, at what distance from the electrical installation the recording is to be made, with what optical magnification the recording is to be made, from what angle the recording is to be made, and/or whether the recording is to be made using flash or additional lighting. Thus, according to advantageous embodiments of the invention, instructions may be given under which conditions and/or in what way the image data are created. This ensures that relevant details for assessing whether the electrical installation is in the proper state are included in the image data. Complete and high-quality data collection is ensured. The second instruction can, for example, be issued to a user of a mobile terminal executing the method according to the invention. The second instruction can be contained, for example, in a text message, an audio message, or the like.

According to the invention, several second instructions can be issued one after the other. For example, the user can first be instructed to capture a specific detail of the electrical installation. The user can then be instructed to set a specific optical magnification. This prevents the user from receiving too many instructions at once. Instead, the user is allowed to make necessary adjustments to the recording step by step. According to the invention, the method can be designed such that a next second instruction is issued only once the requirements according to a previous second instruction have been met. This is preferably implemented by evaluating image data, recorded for example by a mobile terminal, continuously or in real time. This too can be achieved with the support of artificial intelligence or methods from the field of machine learning.

The method preferably further comprises receiving preliminary image data relating to the electrical installation, wherein a check is carried out to determine whether the preliminary image data have at least one deficiency that hinders the evaluation of whether the electrical installation is in the proper state, and wherein the check is preferably carried out based on machine learning and/or artificial intelligence. If the preliminary image data contain the at least one deficiency, a message indicating the at least one deficiency is preferably issued. This makes it possible to determine whether, based on the image data, it is already possible to evaluate whether the electrical installation is in the proper state. If this is not the case, the message can be used, for example, to notify a user of a terminal that is performing the method according to the invention. The message can be, for example, a text message, an audio message, or the like.

The evaluation method, which is based on machine learning and/or artificial intelligence, has preferably been trained such as to be able to perform the inspection described above. For example, the model can be trained using supervised learning to identify defects in image data. Examples can be used to learn in which cases a correct evaluation of the image data is possible and in which cases a correct evaluation of the image data is not possible.

The check for defects is preferably carried out in real time. This means that the preliminary image data will be evaluated immediately or at least as soon as possible. In this sense, the inspection does not begin only after the preliminary image data have been fully recorded, but already during the recording of digital photos or videos. Preferably, feedback regarding detected defects is issued directly to a user, for example a user of a terminal that executes the method according to the invention. According to other embodiments of the invention, however, it is possible for a user to specify when the preliminary image data are complete. Only then will they be checked for defects.

According to advantageous embodiments of the invention, the at least one deficiency consists in that a view of the electrical installation is missing, the electrical installation was recorded from an unsuitable distance, the electrical installation was recorded at an unsuitable angle, the electrical installation was recorded with unsuitable flash or unsuitable lighting, and/or the preliminary image data have inadequate image definition. However, it is understood that according to the invention, other defects in the image data can also be identified. This requires appropriate training of the artificial intelligence used or a machine learning method used.

According to a further aspect of the invention, a system for the periodic inspection of electrical installations, in particular field devices, is proposed, comprising a data processing device, wherein the device is configured to perform the method described above. The system for periodic inspection is advantageously formed by at least one computer. It is also possible for the system for periodic inspection to be formed by a mobile terminal, for example a smartphone or a tablet. The system preferably includes a unit for capturing the image data, in particular a camera.

According to the invention, it is also possible for the system for periodic inspection to be formed by another computer system, for example by a server. According to the invention, the server can be configured, for example, to communicate with a mobile terminal via a network and to receive from the terminal image data and optionally other data captured by the mobile terminal. This could include, for example, user inputs. The computer system is advantageously configured to also send output data to the mobile terminal, for example the report indicating whether the electrical installation is in the proper state. The computer system is preferably configured to perform the evaluation of the image data completely or partially. According to possible variations of the invention, part of the evaluation can also be carried out by other computing units. This also applies to other partial steps or partial aspects of the method. In particular, it is possible for partial aspects of the method to be carried out by the mobile terminal. According to an advantageous variant of the invention, the system for periodic inspection comprises both the computer system and the mobile terminal. The computer system is preferably linked to the mobile terminal via a network connection.

According to a further aspect of the invention, a computer program product is proposed which includes instructions which, when the program is executed by a computer, cause the computer to perform the method described above. The computer program product is preferably executed by the system described above or is intended to be executed thereon. The computer program product is preferably an app for a mobile terminal. However, it could also be software that runs on a different computer system. According to the invention, it is also possible for the computer program product to have several parts, so that it can be executed in a distributed manner, for example on the computer system described above and on the mobile terminal.

Further features and advantages of the invention will become apparent from the drawings, which are intended to clarify the invention for the person skilled in the art so that they can carry it out. However, the drawings do not limit the invention. Nevertheless, the drawings represent advantageous aspects of the invention, the features of which—possibly even individually—can be used to specify the invention to be protected. In the drawings:

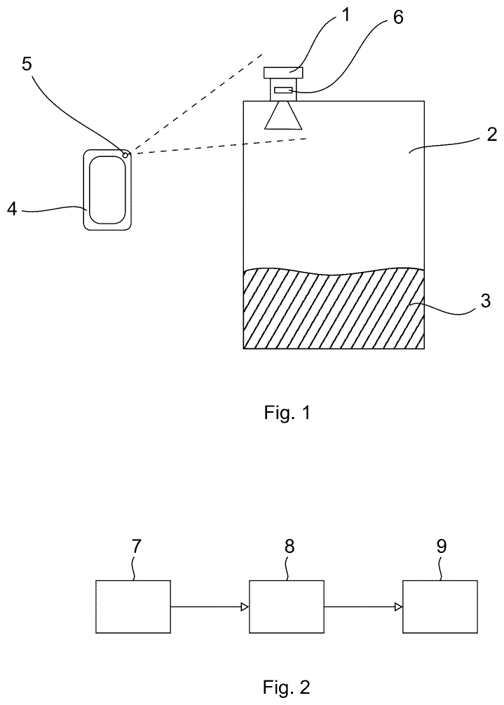

FIG. 1 shows a schematic representation of a scenario with a field device that is subjected to a periodic inspection according to the method according to the invention, and

FIG. 2 shows a flowchart of the method according to the invention.

FIG. 1 shows a schematic representation of a scenario with a field device 1 that is subjected to a periodic inspection according to the method according to the invention. The field device 1 is a fill level measuring device that is installed in a container 2. The container 2 is filled with a liquid 3, the fill level of which is determined by the field device 1 using a radar sensor. A periodic inspection must be carried out at regular intervals. It serves to identify any defects in the field device 1.

To carry out the periodic inspection, a mobile terminal 4 is used, which in the present case is a smartphone. The smartphone is equipped with a camera 5, which can be used to record photos and videos. An app according to the invention for carrying out periodic inspections is installed on the smartphone. When a user starts the app, the app instructs them to take photos and video recordings of the field device 1 using the camera 5. The app gives the user various instructions on how to create the recording. This informs the user whether a photo or video recording should be taken. The user is furthermore informed which sections of the field device 1 should be recorded. If a relevant section of the field device 1 is not visible in the installed state, the app can also notify the user that the field device 1 needs to be removed from the container. The app furthermore provides the user with information on the optical magnification to be used to capture the field device 1. In order to capture even the smallest details, the app also gives the user guidance on the angle from which details of the field device 1 should be captured. Finally, the app also activates the smartphone's flash so that the photos can be recorded in adequate brightness.

While the user is creating the recordings, the app continuously provides feedback on the recordings made. For example, the user will be notified if the images are blurry or if close-up views are missing. Recordings that are unsuitable for evaluation are discarded by the app. Once all required recordings have been made by the user, the app gives feedback to the user that no further recordings need to be made.

The app now performs an evaluation of the image data generated during the recordings to determine whether the field device 1 is in proper state. The image data are evaluated using artificial intelligence, wherein a neural network is employed. The neural network was specifically trained for the evaluation. During evaluation of the image data, the neural network identifies a nameplate 6 of the field device 1. The nameplate contains a model number for the field device 1. Thus, the exact type of field device 1 can be determined and the evaluation can be carried out on this basis. As part of the evaluation, the app according to the invention checks whether the field device 1 is contaminated or damaged. If this is the case, the extent of the contamination or damage will also be determined. Based on this, the app assesses whether the field device 1 is in the proper state.

The app then generates a report that the user can view within the app. The report states whether the field device 1 is in the proper state. If any defects were found in the field device 1, they are also recorded in the report. The report indicates the severity of each defect. Furthermore, the location of the defect in the field device 1 is also indicated. Furthermore, the report includes suggestions on how the user can remedy the defects, if possible. If a defect cannot be remedied by the user, the report suggests having a technician inspect the field device 1.

FIG. 2 shows a flowchart of the method according to the invention. First, in a receiving step 7, an app receives image data relating to an electrical installation. Subsequently, in a evaluation step 8, it is determined whether the electrical installation is in the proper state, wherein the evaluation of the image data is based on machine learning and/or artificial intelligence. Finally, in a generation step 9, a report is generated indicating whether the electrical installation is in the proper state.

According to the invention, the steps mentioned above can be used in different application scenarios. Three exemplary application scenarios of the method are described below.

According to a first application scenario, a periodic inspection of a pressure sensor is carried out in a chemical plant. The inspection includes checking for corrosion on a housing of the pressure sensor, for contamination at a process connection point of the pressure sensor, and for legibility of the nameplates. All of the aforementioned steps can be carried out as part of a visual inspection, so that the method according to the invention can be used. A user opens an app according to the invention on their smartphone, scans a barcode of the pressure sensor and is then guided through the inspection process by the app. The app prompts the user to take photos from specific angles (e.g., front view, side view, close-up of the connection). The app analyzes the image data obtained in this way and identifies a corrosion spot on the housing as well as an illegible type marking. The app then generates a report documenting these anomalies and providing recommendations for treatment, such as corrosion protection or replacement of the pressure sensor.

According to a second application scenario, a periodic inspection of a sensor is carried out in a food processing plant. A temperature sensor in a dairy is checked for hygienic integrity. In this case, it is particularly important that there are no deposits or residues on the housing of the temperature sensor. An app according to the invention assists a user in taking high-resolution images of process connections and the housing of the temperature sensor. During evaluation of the images, the app detects residues which are identified as potential sources of contamination. A report generated by the app suggests cleaning and re-inspection before the temperature sensor is put back into operation.

According to a third application scenario, a visual inspection of a fill level sensor is carried out in a petrochemical installation. The fill level sensor is checked for physical damage as part of a periodic inspection, since the harsh environment is expected to cause increased wear. A user uses the app according to the invention and makes a video showing the entire sensor and its connections. The app analyzes the video and marks a deformed process connection point. The app generates a report documenting the exact location of the deformation and recommending a detailed inspection by a technician.

The method described herein is characterized by the fact that it allows for an objective assessment of electrical installations. This allows for a higher level of safety in electrical installations. The report generated according to the invention is advantageous because it enables complete documentation and traceability of the periodic inspection. Furthermore, this results in time savings compared to the manual creation of inspection reports. The electronically generated inspection results can, for example, be integrated into existing maintenance systems or device databases for long-term condition monitoring.

### LIST OF REFERENCE SIGNS

1 Field device
2 Container
3 Liquid
4 Mobile terminal
5 Camera
6 Nameplate
7 Receiving step
8 Evaluation step
9 Generation step

1. A computer-implemented method for the periodic inspection of electrical installations, in particular field devices, comprising:
receiving image data relating to an electrical installation,
evaluating the image data to determine whether the electrical installation is in the proper state, wherein the evaluation of the image data is based on machine learning and/or artificial intelligence, and
generating a report indicating whether the electrical installation is in the proper state.

2. The computer-implemented method of claim 1, wherein
when the image data is evaluated to determine whether the electrical installation is in the proper state, a check is made as to whether the electrical installation has at least one safety-relevant defect and/or whether the electrical installation complies with current construction standards for the electrical installation.

3. The computer-implemented method of claim 2, wherein
the at least one safety-relevant defect results from aging, wear and tear, operating and/or environmental conditions.

4. The computer-implemented method of claim 2, wherein
the report specifies the at least one defect in the electrical installation, wherein the report optionally includes:
information on the type of the at least one defect,
information on the severity level of the at least one defect,
information on the location of the at least one defect in the electrical installation,
a proposal for remedying the defect, and/or
a proposal for inspection of the electrical installation by a technician.

5. The computer-implemented method of claim 1, wherein
the evaluation of the image data includes:
an assessment of the legibility of a nameplate of the electrical installation,
an assessment of the degree of corrosion of a housing of the electrical installation,
an assessment of the degree of contamination of a process connection point and/or housing of the electrical installation, and/or
an assessment of the degree of physical damage to the electrical installation.

6. The computer-implemented method of claim 1, wherein
the image data include at least one digital photo of the electrical installation and/or at least one video recording of the electrical installation.

7. The computer-implemented method of claim 1, wherein
the method further includes:
receiving type information that specifies a type of the electrical installation, wherein the type information is used as the basis for evaluating the image data.

8. The computer-implemented method of claim 7, wherein
the type information is based on a data input from a user.

9. The computer-implemented method of claim 7, wherein
the type information is extracted from the image data, wherein the type information is determined based on the appearance of the electrical installation, the content of a nameplate of the electrical installation and/or a QR code.

10. The computer-implemented method of claim 9, wherein
the method further includes:
issuing a first instruction to record a digital photo or video of the nameplate of the electrical installation.

11. The computer-implemented method of claim 1, wherein
the method further includes issuing a second instruction to record the image data, wherein the second instruction contains information on
whether a digital photo or video is to be recorded,
which detail of the electrical installation is to be captured by the recording,
at what distance from the electrical installation the recording is to be made,
with what optical magnification the recording is to be made,
from what angle the recording is to be made, and/or
whether the recording is to be made using flash or additional lighting.

12. The computer-implemented method of claim 1, wherein
the method further includes:
receiving preliminary image data relating to the electrical installation,
checking whether the preliminary image data have at least one deficiency that hinders the evaluation of whether the electrical installation is in the proper state, wherein the check is preferably carried out based on machine learning and/or artificial intelligence, and
if the preliminary image data contain the at least one deficiency, issuing a message indicating the at least one deficiency.

13. The computer-implemented method of claim 12, wherein
the at least one deficiency consists in that:
a view of the electrical installation is missing,
the electrical installation was recorded from an unsuitable distance,
the electrical installation was recorded at an unsuitable angle,
the electrical installation was recorded with unsuitable flash or unsuitable lighting, and/or
the preliminary image data have inadequate image definition.

14. A system for the periodic inspection of electrical installations, in particular field devices, comprising a data processing device configured to perform the method of claim 13.

15. A computer program product comprising a non-transitory computer-readable media bearing instructions which, when the program is executed by a computer, cause the computer to perform the method of claim 1.
